(19) United States
(12) Patent Application Publication
(10) Pub. No.: US 2016/0276162 A1
(43) Pub. Date: Sep. 22, 2016

(54) ATOMIC LAYER PROCESS CHAMBER FOR 3D CONFORMAL PROCESSING

(71) Applicant: Applied Materials, Inc., Santa Clara, CA (US)

(72) Inventors: Wei LIU, San Jose, CA (US); Abhilash J. MAYUR, Salinas, CA (US); Phillip STOUT, Santa Clara, CA (US)

(21) Appl. No.: 15/071,479

(22) Filed: Mar. 16, 2016

Related U.S. Application Data
(60) Provisional application No. 62/135,836, filed on Mar. 20, 2015.

(51) Int. Cl. H01L 21/3065; H01L 21/67; H01L 21/687; H01L 21/02

(52) U.S. Cl. CPC H01L 21/3065; H01L 21/02247; H01L 21/67207; H01L 21/67098; H01L 21/68771; H01L 21/02255

(57) ABSTRACT

Embodiments described herein relate to methods for forming or treating material layers on semiconductor substrates. In one embodiment, a method for performing an atomic layer process includes delivering a species to a surface of a substrate at a first temperature, followed by spike annealing the surface of the substrate to a second temperature to cause a reaction between the species and the molecules on the surface of the substrate. The second temperature is higher than the first temperature. By repeating the delivering and spike annealing processes, a conformal layer is formed on the surface of the substrate or a conformal etching process is performed on the surface of the substrate.

### CLAIM OF PRIORITY UNDER 35 U.S.C. 119

This application claims priority to U.S. Provisional Patent Application Ser. No. 62/135,836, filed on Mar. 20, 2015, which herein is incorporated by reference.

### BACKGROUND

1. Field

Embodiments described herein relate to semiconductor manufacturing processes. More specifically, methods for forming or treating material layers on semiconductor substrates are disclosed.

2. Description of the Related Art

Semiconductor device geometries have dramatically decreased in size since their introduction several decades ago. Modern semiconductor fabrication equipment routinely produce devices with 45 nm, 32 nm and 28 nm feature sizes, and new equipment is being developed and implemented to make devices with dimension of less than 12 nm. In addition, the chip architecture is undergoing an inflection point from 2-dimensional (2D) to 3-dimensional (3D) structures for better performing, lower power consuming devices. As a result, conformal deposition of materials to form these devices is becoming increasingly important.

Conformal deposition of materials to form 3D structures may be performed at high temperatures. However, reduced thermal budgets and more stringent critical dimension requirements make high temperature thermal processes unsuitable for advanced device nodes. With reduced thermal budgets, pre-breaking of reactant bonds may be performed by using a plasma or light. However, plasma or light generated ions or radicals based processes are generally not 3D conformal due to the existence of plasma sheath and low pressure (typically less than about 5 Torr) for maintaining the plasma.

Therefore, there is a need in the art for improved methods for forming or treating material layers.

### SUMMARY

Embodiments described herein relate to methods for forming or treating material layers on semiconductor substrates. In one embodiment, a method includes delivering a species to a surface of a substrate. The substrate is at a first temperature, and the species is adsorbed on the surface of the substrate. The method further includes heating the surface of the substrate to a second temperature, and at the second temperature the species reacts with the surface of the substrate. The method further includes repeating the delivering and the heating processes.

In another embodiment, a method includes delivering a species to a surface of a substrate. The substrate is at a first temperature, and the species is adsorbed on the surface of the substrate. The method further includes heating the surface of the substrate to a second temperature, and at the second temperature the species diffuses into the surface of the substrate. The method further includes repeating the delivering and the heating processes.

In another embodiment, a method includes placing a substrate into a process chamber, and delivering a first species to a surface of a substrate. The substrate is at a first temperature, and the first species is adsorbed on the surface of the substrate. The method further includes removing excess first species that is not adsorbed on the surface of the substrate, and heating the surface of the substrate to a second temperature. At the second temperature the first species reacts with the surface of the substrate. The method further includes repeating the delivering and the heating processes.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a processing sequence according to various embodiments.

FIGS. 2A-2C illustrate a process sequence according to one embodiment.

FIGS. 3A-3C illustrate a process sequence according to another embodiment.

FIGS. 4A-4C illustrate a process sequence according to another embodiment.

FIG. 5 is a schematic cross sectional view of a process chamber according to one embodiment.

FIG. 6 is a schematic cross sectional view of a process chamber according to another embodiment.

FIG. 7 is a schematic cross sectional top view of a process chamber according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to methods for forming or treating material layers on semiconductor substrates. In one embodiment, a method for performing an atomic layer process includes delivering a species to a surface of a substrate at a first temperature, followed by spike annealing the surface of the substrate to a second temperature to cause a reaction between the species and the molecules on the surface of the substrate. The second temperature is higher than the first temperature. By repeating the delivering and spike annealing processes, a conformal layer is formed on the surface of the substrate or a conformal etching process is performed on the surface of the substrate.

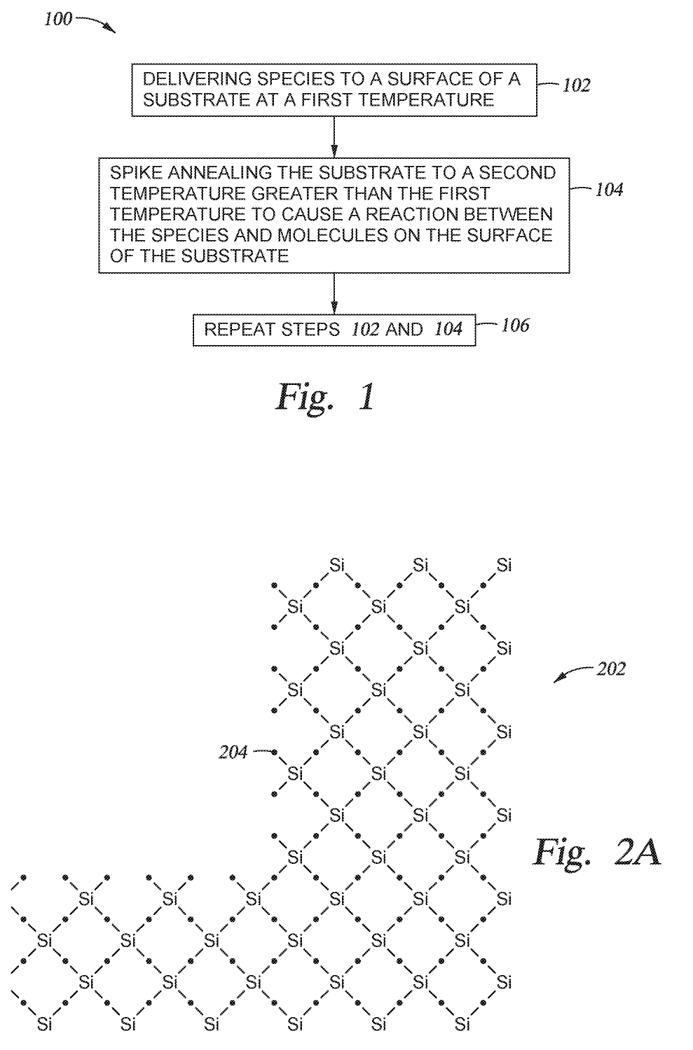

FIG. 1 illustrates a processing sequence 100 according to various embodiments. The processing sequence 100 may be an atomic layer process performed on a surface of a substrate. The processing sequence 100 begins at block 102. At block 102, a species is delivered to a surface of a substrate. The substrate may be any suitable substrate, such as a silicon substrate, and the surface of the substrate may include silicon molecules. In some embodiments, a dielectric layer, such as an oxide layer, may be formed on the substrate, and the surface of the substrate may include oxide molecules. The surface of the substrate may include a plurality of features. The substrate may be disposed inside of a process chamber. In one embodiment, the process chamber includes one processing station. In another embodiment, the process chamber includes two processing stations. In other embodiments, the process chamber includes more than two processing stations. The delivering of the species to the surface of the substrate may be performed at one processing station in the process chamber with two or more processing stations.

The species may be any suitable species, such as one or more gases or radicals. The radicals may be formed remotely and then delivered to the surface of the substrate. Alternatively, the radicals may be formed by energizing a gas introduced into the process chamber. The plasma source used to energize the gas inside the process chamber may be any suitable plasma source, such as a capacitively coupled plasma source, an inductively coupled plasma source, or a microwave plasma source. The species may be introduced to the surface of the substrate while the substrate is heated or cooled to a first temperature. At the first temperature, the species would not react with the molecules on the surface of the substrate. Instead, the species is adsorbed on the surface of the substrate until the surface is saturated with the species. The first temperature of the substrate is high enough to cause the species to be adsorbed on the surface of the substrate and low enough to avoiding a reaction between the species and the molecules on the surface of the substrate. The saturation of the species at the surface of the substrate is a self limiting process since there is no reaction between the species and the molecules on the surface of the substrate due to the first temperature.

At block 104, a spike annealing process is performed on the substrate. The spike annealing process is capable of rapidly increasing the temperature of the surface of the substrate to a second temperature without substantially increasing the temperature of the remaining of the substrate. The spike annealing process may be performed on the substrate in the same process chamber. In one embodiment, the process chamber includes two processing stations, the delivering of the species to the surface of the substrate is performed at one processing station and the substrate is transferred to the other processing station at which the spike annealing process is performed. A purging process may be performed following the delivering of the species to the surface of the substrate and prior to the spike annealing process in order to remove excess species that is not adsorbed on the surface of the substrate.

The dwelling time, or the time of heating the substrate with a flash heating source, such as lasers or flash lamps, may be short, such as about 1 microsecond. Because the dwelling time is short and the temperature of the bulk of the substrate is not substantially increased, a quick dissipation of the heat through the bulk of the substrate during cool down period is ensured. The cool down period from the second temperature at the surface of the substrate back to the starting temperature is also short, such as from about 10 to 100 microseconds.

When the surface of the substrate is rapidly heated to the second temperature, such as over 1000 degrees Celsius, the species adsorbed on the saturated surface of the substrate becomes reactive with the molecules of the surface of the substrate. The second temperature may range from about 1000 degrees Celsius to about 1300 degrees Celsius. In one embodiment, the species is diffused into the surface of the substrate. In another embodiment, the species breaks away a portion of the surface of the substrate conformally by forming a product with the portion of the surface of the substrate. In yet another embodiment, a second species is introduced into the process chamber, and at the second temperature, the second species reacts with the species on the surface of the substrate, forming a conformal layer on the surface of the substrate.

Next, at block 106, the processes described at blocks 102 and 104 are repeated. As a result of the repeated processes described at blocks 102 and 104, a conformal layer may be formed on the surface of the substrate or diffused into the surface of the substrate. Alternatively, repeating the processes described at blocks 102 and 104 may remove a portion of the surface conformally.

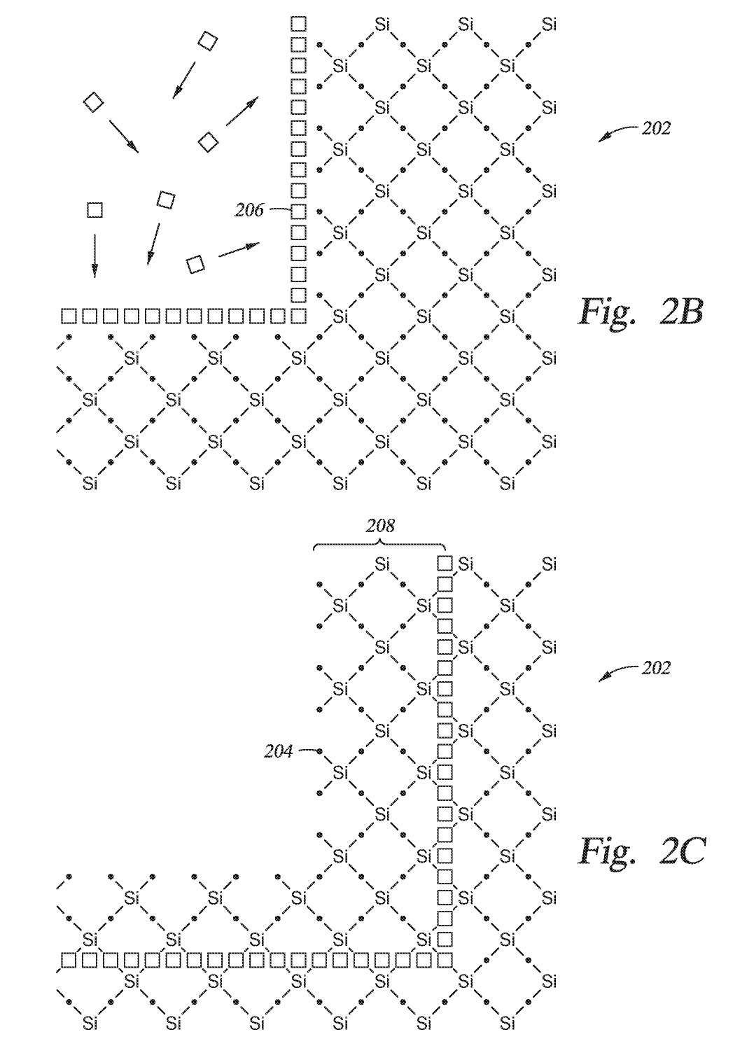

FIGS. 2A-2C illustrate the processing sequence 100 according to one embodiment. As shown in FIG. 2A, a surface 204 of a substrate (not shown) may include a feature 202. The feature 202 is made of silicon dioxide, as shown in FIG. 2A. However, the material of the feature 202 may not be limited to silicon dioxide. In some embodiments, the feature 202 is made of silicon. The substrate having the surface 204 is placed on a substrate support inside a process chamber. In some embodiments, the substrate having the surface 204 is placed on a substrate support at a first processing station in a process chamber. The surface 204 may have been cleaned by a cleaning process to remove any contaminants from the surface 204. The cleaning process may be any suitable cleaning process, such as a cleaning process utilizing a halogen based cleaning gas or radicals, such as a chlorine or fluorine based gas or radicals. The substrate may reach a first temperature by a temperature control device formed in the substrate support. The first temperature may vary based on the types of species and materials of the surface 204. The first temperature is low enough so there is no reaction between the species and the surface 204.

A species 206 is introduced into the process chamber or the processing station of the process chamber, as shown in FIG. 2B. The species 206 adsorbs on the surface 204 until the surface 204 is saturated with the species 206. Again the species may be any suitable species, such as one or more gases or radicals. In one embodiment, the species 206 is nitrogen containing radicals, such as NH* radicals. In another embodiment, the species 206 is a boron containing species, such as a boron containing gas or boron containing radicals. The boron containing radicals may be B*, BHₓ*, or any suitable boron containing radicals.

In one embodiment, the species 206 is formed by introducing a boron containing gas into a processing region of the process chamber including the substrate having the surface 204 disposed therein. The boron containing gas may be any suitable boron containing gas, such as B₂H₆. The boron containing gas may be activated by a plasma source, such as a capacitively coupled plasma source, an inductively coupled plasma source, or a microwave plasma source, to form a plasma containing the species 206. The species 206 may be boron containing radicals, such as B* or BHₓ*, where x may be 1, 2 or 3. In another embodiment, the species 206 is formed by flowing a boron containing gas into a remote plasma source coupled to the processing chamber including the substrate having the surface 204 disposed therein. The boron containing gas may be any suitable boron containing gas, such as B₂H₆. The boron containing gas may be activated by the remote plasma source to form a plasma containing the species 206. The species 206 may be boron containing radicals, such as B* or BH_{X}*, where x may be 1, 2 or 3. The species 206 are flowed into the processing region of the processing chamber.

Next, as shown in FIG. 2C, the temperature of the surface 204 is rapidly increased to a second temperature, and the species 206 becomes reactive with the molecules of the surface 204. In one embodiment, the species 206 is diffused into the feature 202. The temperature of the surface 204 of the substrate may be rapidly increased by a spike annealing process. The spike annealing process may be performed in the same process chamber. In some embodiments, the substrate is transferred to a second processing station inside the processing chamber, and the spike annealing process is performed at the second processing station. As a result of repeating the processes described in FIGS. 2B and 2C, a portion 208 of the feature 202 is modified, such as nitridated.

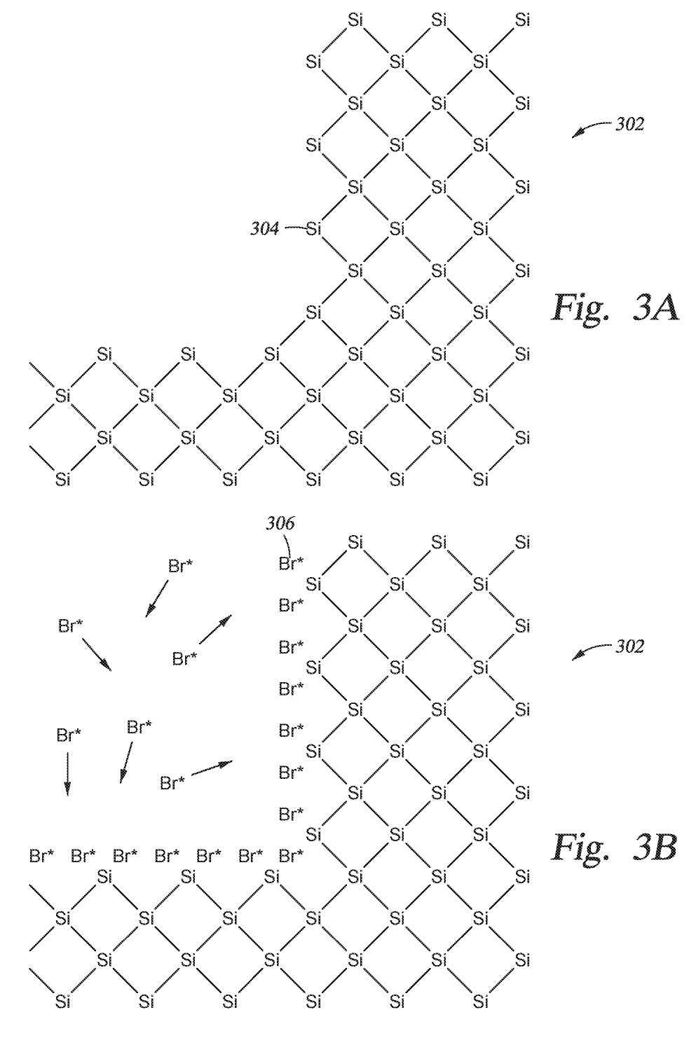

FIGS. 3A-3C illustrate the processing sequence 100 according to another embodiment. As shown in FIG. 3A, a surface 304 of a substrate (not shown) may include a feature 302. The feature 302 is made of silicon, as shown in FIG. 3A. However, the material of the feature 302 may not be limited to silicon. The substrate having the surface 304 is placed on a substrate support inside a process chamber. In some embodiments, the substrate having the surface 304 is placed on a substrate support at a first processing station in a process chamber. The substrate may reach a first temperature by a temperature control device formed in the substrate support. The first temperature may vary based on the types of species and materials of the surface 304. The first temperature is low enough so there is no reaction between the species and the surface 304.

A species 306 is introduced into the process chamber or the processing station of the process chamber, as shown in FIG. 3B. The species 306 adsorbs on the surface 304 until the surface 304 is saturated with the species 306. Again the species may be any suitable reactive species, such as one or more gases or radicals. In one embodiment, the species 306 is Br* or other halogen radicals.

Next, as shown in FIG. 3C, the temperature of the surface 304 is rapidly increased to a second temperature, and the species 306 becomes reactive with the molecules of the surface 304. In one embodiment, the species 306 and the silicon molecules of the surface 304 forms a product 308, such as SiBrₓ, and the product 308 is removed from the surface 304. The temperature of the surface 304 of the substrate may be rapidly increased by a spike annealing process. The spike annealing process may be performed in the same process chamber. In some embodiments, the substrate is transferred to a second processing station inside the processing chamber, and the spike annealing process is performed at the second processing station. As a result of repeating the processes described in FIGS. 3B and 3C, a conformal etching process may be performed on the surface 304, and a portion of the feature 302 having a substantially uniform thickness may be removed.

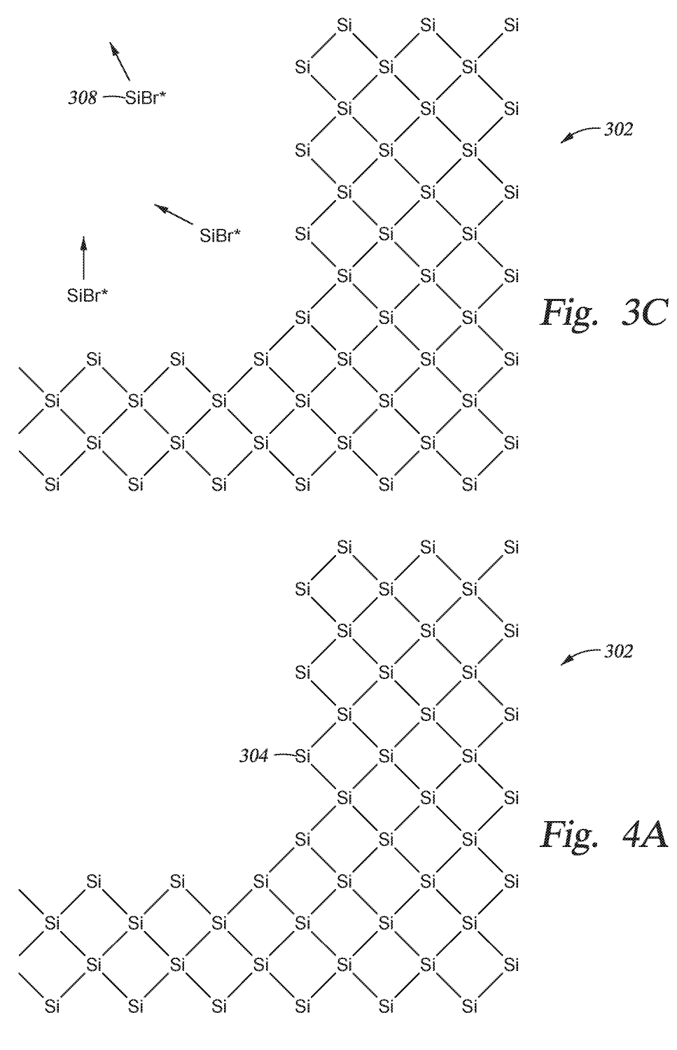

FIGS. 4A-4C illustrate the processing sequence 100 according to another embodiment. As shown in FIG. 4A, the surface 304 of a substrate (not shown) may include a feature 302. The feature 302 is made of silicon, as shown in FIG. 4A. However, the material of the feature 302 may not be limited to silicon. The substrate having the surface 304 is placed on a substrate support inside a process chamber. In some embodiments, the substrate having the surface 304 is placed on a substrate support at a first processing station in a process chamber. The substrate may reach a first temperature by a temperature control device formed in the substrate support. The first temperature may vary based on the types of species and materials of the surface 304. The first temperature is low enough so there is no reaction between the species and the surface 304.

A species 406 is introduced into the process chamber or the processing station of the process chamber, as shown in FIG. 4B. The species 406 adsorbs on the surface 304 until the surface 304 is saturated with the species 406. Again the species may be any suitable species, such as one or more gases or radicals. In one embodiment, the species 406 is nitrogen containing radicals or gases, such as NH* radicals or ammonia gas.

Next, as shown in FIG. 3C, the temperature of the surface 304 is rapidly increased to a second temperature, and a second species 408 is introduced into the process chamber or the second processing station of the process chamber. The second species 408 may be trimethylsilane. At the second temperature, the species 406 becomes reactive with the second species 408. In one embodiment, the species 406 and the second species 408 form a product, such as SiCN, on the surface 304. The temperature of the surface 304 of the substrate may be rapidly increased by a spike annealing process so the surface 304 reaches the second temperature. The spike annealing process may be performed in the same process chamber. In some embodiments, the substrate is transferred to a second processing station inside the processing chamber, and the spike annealing process is performed at the second processing station. As a result of repeating the processes described in FIGS. 4B and 4C, a conformal layer may be formed on the surface 304. The conformal layer may be SiCN.

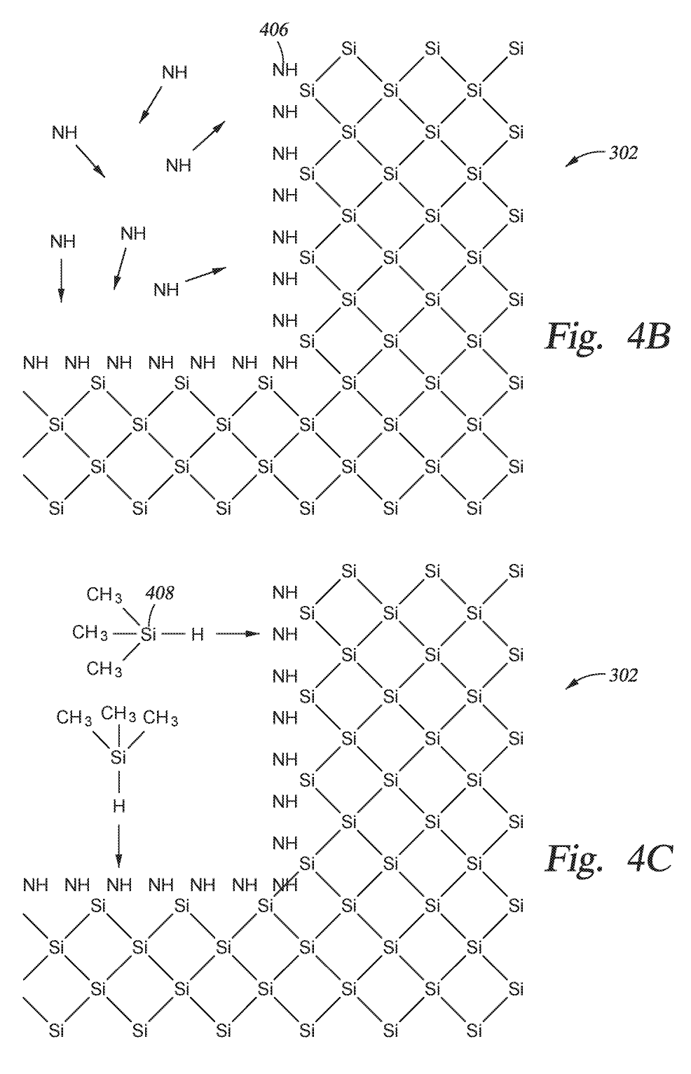

FIG. 5 is a schematic cross sectional view of a process chamber 500 according to one embodiment. The processing sequence 100 may be performed in the process chamber 500. The process chamber 500 includes a bottom 502, a side wall 504 and a top 506, defining a processing region 507. A substrate support 508 may be disposed in the processing region 507, and a substrate 512 may be disposed on the substrate support 508. A temperature control element 510, such as a heating element or cooling channel, may be formed in the substrate support 508 for controlling temperature of the substrate 512. A flash heating source 514 may be disposed over the substrate support 508 for performing the spike annealing process. The flash heating source 514 may include a plurality of lasers or flash lamps. A species injection port 516 may be formed in the side wall 504, and a species source 518 may be connected to the species injection port 516. The sequence of delivering of the species to the surface of the substrate and spike annealing described above may be performed in the process chamber 500. The process chamber 500 may include a purging gas injection port (not shown) that is connected to a purging gas source (not shown) for purging the processing region 507.

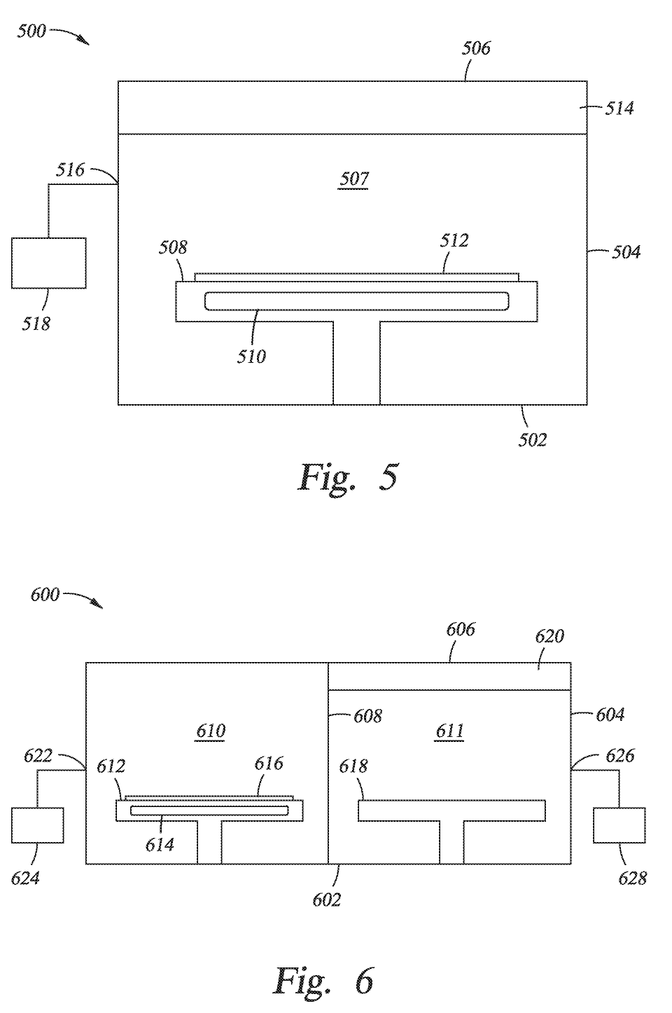

FIG. 6 is a schematic cross sectional view of a process chamber 600 according to one embodiment. The processing sequence 100 may be performed in the process chamber 600. The process chamber 600 includes a bottom 602, a side wall 604 and a top 606. A divider 608 may be disposed in the process chamber 600 and may form two processing stations 610, 611. The divider 608 may be a physical divider or an air curtain. The first processing station 610 may include a substrate support 612 and a temperature control element 614 embedded in the substrate support 612. The temperature control element 614 may be the same as the temperature control element 510 described in FIG. 5.

A species injection port 622 may be formed in the side wall at the first processing station 610, and a species source 624 may be coupled to the species injection port 622. The first processing station 610 may further include a purging gas injection port (not shown) that is connected to a purging gas source (not shown) for purging the processing station 610.

The second processing station 611 may include a substrate support 618 for supporting the substrate 616. The substrate support 618 may include a temperature control element (not shown) that is the same as the temperature control element 614. A flash heating source 620 may be disposed over the substrate support 618. The flash heating source 620 may be the same as the flash heating source 514 described in FIG. 5. The second processing station 611 may further include a species injection port 626, and a species source 628 may be coupled to the species injection port 626. The species source 628 and the species injection port 626 may be utilized to deliver a second specie to the surface of the substrate 616. The substrate 616 may be moved to the first processing station 610 and the second processing station 611 in order to have the processing sequence 100 performed thereon.

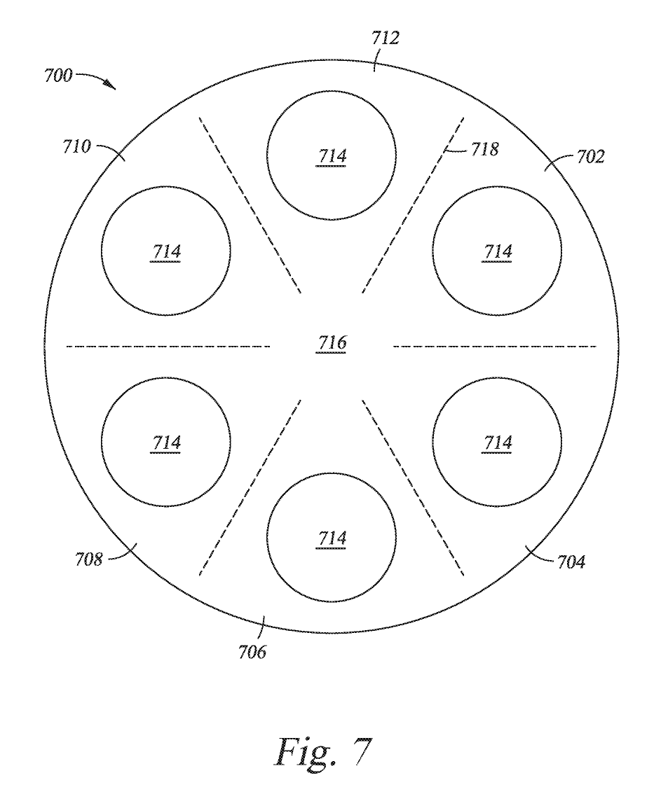

FIG. 7 is a schematic cross sectional top view of a process chamber 700 according to one embodiment. The process chamber 700 may include a plurality of processing stations 702, 704, 706, 708, 710, 712 (six are shown but are not limited to six). Each processing station 702, 704, 706, 708, 710, 712 includes a substrate holder 714 for supporting a substrate (not shown). The substrate holders 714 may be formed on a substrate support 716. The substrate support 716 may include a temperature control element (not shown) for controlling the temperature of the substrates disposed on the substrate holder 714. The plurality of processing stations 702, 704, 706, 708, 710, 712 may be separated by a divider 718, which may be a physical divider or an air curtain. Some of the plurality of processing stations may be capable of performing delivering a species to a surface of the substrate at the first temperature, while the remaining processing stations may be capable of performing spike annealing process. In one embodiment, the delivering of the species to the surfaces of the substrates is performed at processing stations 702, 706, 710. After the surfaces of the substrates are saturated with the species, the substrate support 716 rotates to place the substrates at processing stations 704, 708, 712, at which the spike annealing process may be performed. The substrate support 716 may be rotated to place the substrates at selected processing stations in order to perform the processing sequence 100.

While the foregoing is directed to embodiments, other and further embodiments may be devised without departing from the basic scope thereof, and the scope thereof is determined by the claims that follow.

1. A method, comprising:
delivering a species to a surface of a substrate, wherein the substrate is at a first temperature, wherein the species is adsorbed on the surface of the substrate;
heating the surface of the substrate to a second temperature, wherein at the second temperature the species reacts with the surface of the substrate; and
repeating the delivering and the heating processes.

2. The method of claim 1, wherein the second temperature is greater than the first temperature, and the second temperature ranges from about 1000 degrees Celsius to about 1300 degrees Celsius.

3. The method of claim 1, wherein the species comprises radicals.

4. The method of claim 1, wherein the species comprises one or more gases.

5. The method of claim 1, wherein the species comprises halogen radicals or nitrogen containing radicals or gas.

6. The method of claim 5, wherein the species is halogen radicals and the surface of the substrate comprises silicon, and at the second temperature the halogen radicals react with silicon to form a product, wherein the produce is removed from the surface of the substrate.

7. The method of claim 6, wherein the repeating of the delivering and heating processes is a conformal etching process.

8. A method, comprising:
delivering a species to a surface of a substrate, wherein the substrate is at a first temperature, wherein the species is adsorbed on the surface of the substrate;
heating the surface of the substrate to a second temperature, wherein at the second temperature the species diffuses into the surface of the substrate; and
repeating the delivering and the heating processes.

9. The method of claim 8, wherein the second temperature is greater than the first temperature, and the second temperature ranges from about 1000 degrees Celsius to about 1300 degrees Celsius.

10. The method of claim 8, wherein the species comprises radicals.

11. The method of claim 10, wherein the species comprises nitrogen containing radicals or boron containing radicals.

12. The method of claim 11, wherein the surface of the substrate comprises silicon dioxide or silicon.

13. The method of claim 12, wherein the repeating of the delivering and heating processes is a nitridation process.

14. A method, comprising:
placing a substrate into a process chamber;
delivering a species to a surface of the substrate, wherein the substrate is at a first temperature, wherein is adsorbed on the surface of the substrate;
removing excess species that is not adsorbed on the surface of the substrate;
heating the surface of the substrate to a second temperature, wherein the second temperature is greater than the first temperature, wherein at the second temperature the species reacts with the surface of the substrate; and
repeating the delivering and the heating processes.

15. The method of claim 14, wherein the delivering of the species to the surface of the substrate is performed at a first processing station of the process chamber, and the heating of the surface of the substrate is performed at a second processing station of the process chamber.

16. The method of claim 15, wherein the process chamber includes a plurality of processing stations.

17. The method of claim 16, wherein the process chamber includes six processing stations, wherein three are used for delivering the species to the surface of the substrate and three are used for heating the surface of the substrate.

18. The method of claim 17, further comprising placing six substrates on a substrate support and placing the substrate support into the process chamber.

19. The method of claim 18, further comprising rotating the substrate support to place a substrate at a corresponding processing station within the process chamber.

20. The method of claim 14, wherein the second temperature ranges from about 1000 degrees Celsius to about 1300 degrees Celsius.
